(19) United States
(12) Patent Application Publication
(10) Pub. No.: US 2021/0134693 A1
(43) Pub. Date: May 6, 2021

(54) SEMICONDUCTOR PACKAGE

(71) Applicant: KIOXIA CORPORATION, Tokyo (JP)

(72) Inventor: Manabu MATSUMOTO, Yokohama Kanagawa (JP)

(21) Appl. No.: 16/937,159

(22) Filed: Jul. 23, 2020

(30) Foreign Application Priority Data
Nov. 6, 2019 (JP) 2019-201489

(51) Int. Cl. H01L 23/31; H01L 25/18

(52) U.S. Cl. CPC H01L 23/3142; H01L 25/18

(57) ABSTRACT

A semiconductor package includes a substrate having a first surface, at least one memory chip including a first memory chip provided on the first surface, a controller chip configured to control the first memory chip, and provided on the first surface to be spaced apart from the first memory chip, a sealing member sealing the first memory chip and the controller chip, and a first member covering at least part of the controller chip and has a lower thermal conductivity than that of the sealing member.

### CROSS-REFERENCE TO RELATED APPLICATION(S)

This application is based upon and claims the benefit of priority from Japanese Patent Application No. 2019-201489, filed Nov. 6, 2019, the entire contents of which are incorporated herein by reference.

### FIELD

Embodiments described herein relate generally to a semiconductor package.

### BACKGROUND

A semiconductor package configured with a semiconductor memory chip and a controller chip that controls the semiconductor memory chip is provided.

### BRIEF DESCRIPTION OF THE DRAWINGS

FIG. 1 is a schematic diagram showing part of a configuration of an electronic apparatus including a circuit board on which a semiconductor package according to a first embodiment is mounted.

FIG. 2 is a block diagram showing an example of a configuration of the semiconductor package according to the first embodiment.

FIG. 3A is a cross-sectional view of one example of the semiconductor package according to the first embodiment.

FIG. 3B is a cross-sectional view of another example of the semiconductor package according to the first embodiment.

FIG. 4 is a top view of the semiconductor package according to the first embodiment.

FIG. 5 is a cross-sectional view of a semiconductor package according to a modification of the first embodiment.

FIG. 6 is a cross-sectional view of a semiconductor package according to a second embodiment.

FIG. 7 is a top view of the semiconductor package according to the second embodiment that excludes some of the elements of the semiconductor package.

FIG. 8 is a top view of the semiconductor package according to the second embodiment.

FIG. 9 is a cross-sectional view of a semiconductor package according to a modification of the second embodiment.

FIG. 10 is a cross-sectional view of a first example of a semiconductor package according to a third embodiment.

FIG. 11 is a cross-sectional view of a second example of the semiconductor package according to the third embodiment.

FIG. 12 is a top view of a third example of the semiconductor package according to the third embodiment.

FIG. 13 is a top view of a fourth example of the semiconductor package according to the third embodiment.

FIG. 14 is a cross-sectional view of a fifth example of the semiconductor package according to the third embodiment.

FIG. 15 is a cross-sectional view of a sixth example of the semiconductor package according to the third embodiment.

FIG. 16 is a top view of the semiconductor package according to the third embodiment.

### DETAILED DESCRIPTION

An embodiment provides a semiconductor package capable of having improved reliability.

In general, according to one embodiment, a semiconductor package includes a substrate having a first surface, at least one memory chip including a first memory chip provided on the first surface, a controller chip configured to control the first memory chip, and provided on the first surface to be spaced apart from the first memory chip, a sealing member sealing the first memory chip and the controller chip, and a first member covering at least part of the controller chip and has a lower thermal conductivity than that of the sealing member.

Embodiments for implementing the disclosure will be described hereinafter.

In the present specification, a plurality of expressions are given to some elements. These expressions are given as an example only and are not intended to preclude any other expressions. Furthermore, elements to which a plurality of expressions are not given may be expressed by other expressions.

The drawings are schematic and the relations between thicknesses and plane dimensions, ratios of thicknesses of layers, and the like often differ from actual ones. Furthermore, the relations of dimensions and ratios often differ among the drawings.

First, +X direction, −X direction, +Y direction, −Y direction, +Z direction, and −Z direction will be defined. The +X direction is a direction that is horizontal to a substrate 21 to be described later and that extends from a controller chip 11 to a semiconductor memory chip 12. The −X direction is a direction opposite to the +X direction. In a case of no discrimination between the +X direction and the −X direction, “X direction” is simply used. The +Y direction is a direction that is horizontal to the substrate and that crosses (for example, that is generally orthogonal to) the +X direction. The −Y direction is a direction opposite to the +Y direction. In a case of no discrimination between the +Y direction and the −Y direction, “Y direction” is simply used. The +Z direction is a direction that is perpendicular to the substrate 21 and that crosses (for example, that is generally orthogonal to) the X direction and the Y direction, and is a direction that extends from the substrate 21 to the controller chip 11. The −Z direction is a direction that extends from the substrate 21 to solder balls 25 and that is opposite to the +Z direction. In a case of no discrimination between the +Z direction and the −Z direction, “Z direction” is simply used. The Z direction is, for example, a thickness direction of the substrate 21.

### First Embodiment

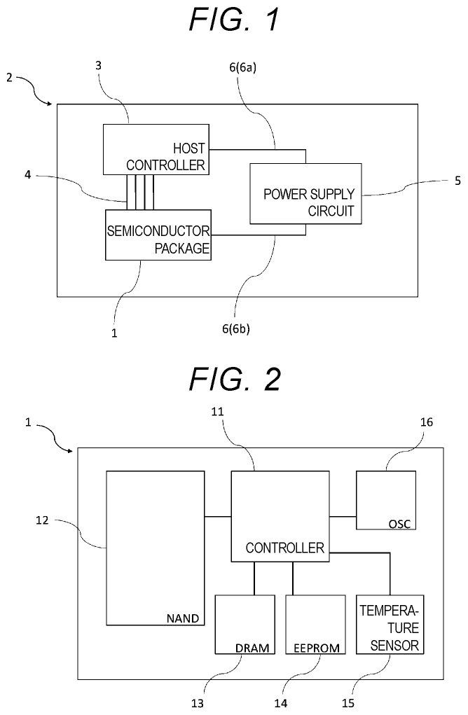

FIGS. 1 to 5 show a semiconductor package 1 according to a first embodiment. The semiconductor package 1 is an example of a semiconductor device. The semiconductor package 1 according to the present embodiment is, for example, a BGA-SSD (Ball Grid Array-Solid State Drive), and at least one semiconductor memory chip and a controller chip that controls the semiconductor memory chip are integrally configured as one BGA type package. Such a semiconductor package is mounted in an electronic apparatus such as a personal computer (PC) or a cellular telephone and functions as a storage device of the electronic apparatus.

FIG. 1 schematically illustrates part of a configuration of a circuit board 2 used when the semiconductor package 1 is attached to an electronic apparatus. The circuit board 2 includes a host controller 3, signal lines 4, a power supply circuit 5, and power-supply lines 6 (6a, 6b). The host controller 3 and the semiconductor package 1 according to the present embodiment each have an interface compliant with, for example, standards of PCI Express (PCIe)®. The plurality of signal lines 4 are provided between the host controller 3 and the semiconductor package 1. The semiconductor package 1 exchanges high speed signals compliant with PCIe standard with the host controller 3 via the signal lines 4. The power supply circuit 5 is connected to the host controller 3 and the semiconductor package 1 via the power-supply lines (6a, 6b). The power-supply line 6a connects the power supply circuit 5 to the host controller 3, and the power-supply line 6b connects the power supply circuit 5 to the semiconductor package 1. The power supply circuit 5 supplies power for operating the electronic apparatus to the host controller 3 and the semiconductor package 1.

Communication interfaces between the host controller 3 and the semiconductor package 1 may be compliant with standards such as Serial Attached SCSI (SAS), Serial Advanced Technology Attachment (SATA), Universal Serial Bus (USB), Peripheral Component Interconnect Express (PCIe), or the like.

The host controller 3 mounted in the electronic apparatus is, for, a CPU, and controls the overall electronic apparatus, which includes the storage device connected to or mounted in the electronic apparatus.

A configuration of the semiconductor package 1 will next be described.

FIG. 2 is a block diagram showing an example of the configuration of the semiconductor package 1. The semiconductor package 1 may be configured with the controller chip 11, the semiconductor memory chip 12, a DRAM chip 13, an oscillator (OSC) 14, an Electrically Erasable and Programmable ROM (EEPROM) 15, and a temperature sensor 16.

The controller chip 11 is a semiconductor chip that exercises control to operate the semiconductor memory chip 12. The semiconductor memory chip 12 is, for example, a NAND flash memory (NAND chip). The NAND chip is a nonvolatile memory and retains data even in a state in which power is not supplied. The DRAM chip (DRAM) 13 is used to cache data and to store management information about the semiconductor memory chip 12.

The oscillator (OSC) 14 supplies a signal of a predetermined frequency to the controller chip 11. The EEPROM 15 is an example of a nonvolatile memory that stores a control program and the like. The temperature sensor 16 detects an internal temperature of the semiconductor package 1 and notifies the controller chip 11 of the temperature.

Since power consumption of the controller chip 11 is high, compared with the semiconductor chips mounted in the semiconductor package 1, a temperature of the controller chip 11 tends to be higher than those of the other semiconductor chips. When heat of the controller chip 11 is transferred to the other semiconductor chips, performances of the other semiconductor chips degrade.

In a case of, for example, the DRAM chip 13, when a temperature rises, then efficiency of a refresh cycle degrades and data loss tends to occur. Furthermore, in a case of a nonvolatile semiconductor memory chip such as the NAND chip 12, when a temperature rises, then a data retention capability is lowered and reliability of data stored in the semiconductor memory chip degrades.

A structure of the semiconductor package 1 according to the first embodiment will next be described.

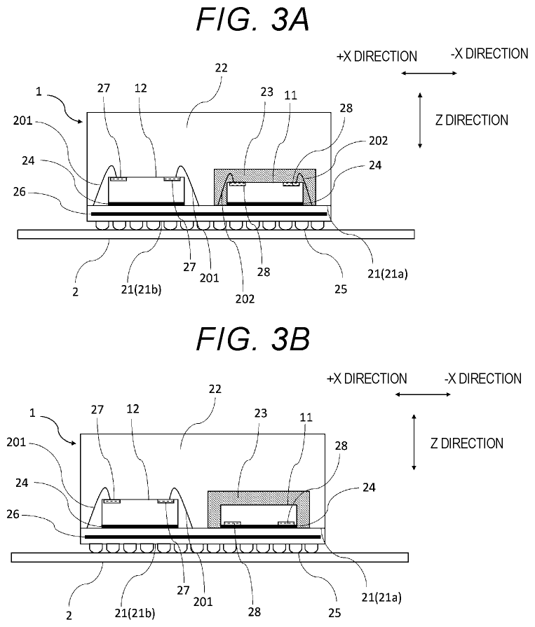

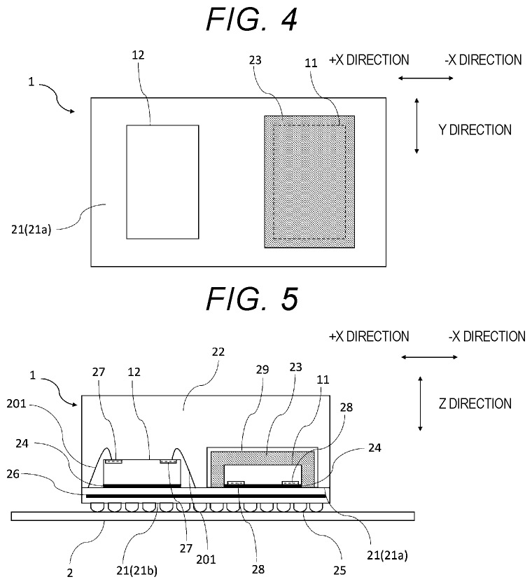

FIGS. 3A and 3B are cross-sectional views of the semiconductor package 1 and FIG. 4 is a top view of the semiconductor package 1. For the sake of convenience of description, some elements such as the oscillator 14 and the EEPROM 15 provided in the semiconductor package 1 are not shown in FIGS. 3A, 3B, and 4. Moreover, the semiconductor memory chips are also referred to as “memory chips”, hereinafter.

The semiconductor package 1 is configured with the substrate 21, the controller chip 11, at least one semiconductor memory chip 12, a sealing member 22, a first member 23, and a plurality of solder balls 25.

The substrate 21 includes a mounting film 24 provided on a surface thereof and an internal interconnection 26 (e.g., an interconnecting wiring layer) provided in an interior thereof. The substrate 21 has a first surface 21a and a second surface 21b located on an opposite side to the first surface 21a.

The controller chip 11 is provided on the first surface 21a. The controller chip 11 is fixed onto the substrate 21 by the mounting film 24. The controller chip 11 has electrode pads 28 and is electrically connected to the internal interconnection 26 via the electrode pads 28. The controller chip 11 is connected to the internal interconnection 26, for example, by wire bonding using wires 202 as shown in FIG. 3A, or by flip-chip bonding as shown in FIG. 3B.

The semiconductor memory chip 12 is provided on the first surface 21a spaced apart from the controller chip 11 in the X direction, and fixed onto the substrate 21 by the mounting film 24. The semiconductor memory chip 12 has electrode pads 27. The semiconductor memory chip 12 is electrically connected to the internal interconnection 26 by wire bonding in such a manner, for example, that wires 201 are connected to the electrode pads 27. The semiconductor memory chip 12 is electrically connected to the controller chip 11 via the internal interconnection 26.

The sealing member 22 is a member that seals the controller chip 11 and the semiconductor memory chip 12 on the substrate 21.

The mounting film 24 that fixes the controller chip 11 may be higher in thermal conductivity than the sealing member 22. In this case, the mounting film 24 functions to efficiently transfer heat of the controller chip 11 to the substrate 21.

The first member 23 is provided on the first surface 21a and covers at least part of surroundings of the controller chip 11. The surroundings refer herein to surfaces other than a surface of the controller chip 11 on which the controller chip 11 is in contact with the substrate 21. Furthermore, the first member 23 is located between the controller chip 11 and the semiconductor memory chip 12 in the X direction. The first member 23 is lower in thermal conductivity than the sealing member 22 and thus it is difficult to transfer the heat generated by the controller chip 11 to the semiconductor memory chip 12 by the first member 23.

The substrate 21 has the solder balls 25 provided on the second surface 21b and can be, therefore, electrically connected to the circuit board 2 of the electronic apparatus via the solder balls 25.

In the structure described above, the first member 23 makes it difficult to transfer the heat of the controller chip 11 to the sealing member 22 and also to the other semiconductor chips such as the semiconductor memory chip 12. Furthermore, the heat of the controller chip 11 is dissipated in a direction of the circuit board 2 via the mounting film 24, the substrate 21, and the solder balls 25. It is, therefore, possible to reduce an influence of thermal conduction on the other semiconductor chips such as the semiconductor memory chip 12 within the semiconductor package 1 and prevent a decline in function due to the heat.

(Modification)

The semiconductor package according to the present embodiment may be configured with a second member 29 as shown in FIG. 5. The second member 29 covers at least part of surroundings of the first member 23. The surroundings refers herein to surfaces of the first member 23 other than a surface on which the first member 23 is in contact with the substrate 21. Furthermore, the second member 29 is located between the first member 23 and the semiconductor memory chip 12 in the X direction. The second member 29 may be lower in thermal conductivity than, for example, the sealing member 22 and also lower in thermal conductivity than the first member 23.

In a case in which the second member 29 is lower in thermal conductivity than the first member 23, it is possible to prevent the heat of the controller chip 11, which is not completely shielded by the first member 23, from being transferred to the other semiconductor chips. Shielding of the heat means herein that the heat of the controller chip 11 is made difficult to be transferred to the semiconductor chips such as the semiconductor memory chip 12 via the first member 23 or the second member 29 rather than via the sealing member 22.

In the structure, similarly to the structure according to the first embodiment, the first member 23 or the second member 29 makes it difficult to transfer the heat of the controller chip 11 to the sealing member 22 and also to the other semiconductor chips such as the semiconductor memory chip 12. Furthermore, the heat of the controller chip 11 is dissipated in the direction of the circuit board 2 via the mounting film 24, the substrate 21, and the solder balls 25. It is, therefore, possible to suppress the influence of thermal conduction on the other semiconductor chips such as the semiconductor memory chip 12 within the semiconductor package 1 and prevent a decline in function due to the heat.

The sealing member 22, the first member 23, and the second member 29 may be made from, for example, phenol resin, epoxy resin, polyethylene terephthalate (PET), carbon black (carbon fine particles at a diameter of approximately 3 to 500 nm), silica (silicon dioxide), or a mixture thereof. Changing a mixture ratio and reducing a content of a material (for example, metal such as carbon black or silica) having high thermal conductivity make it possible to reduce the thermal conductivity.

In the present embodiment, a plurality of semiconductor memory chips 12 may be stacked.

### Second Embodiment

A structure of the semiconductor package 1 according to a second embodiment will next be described.

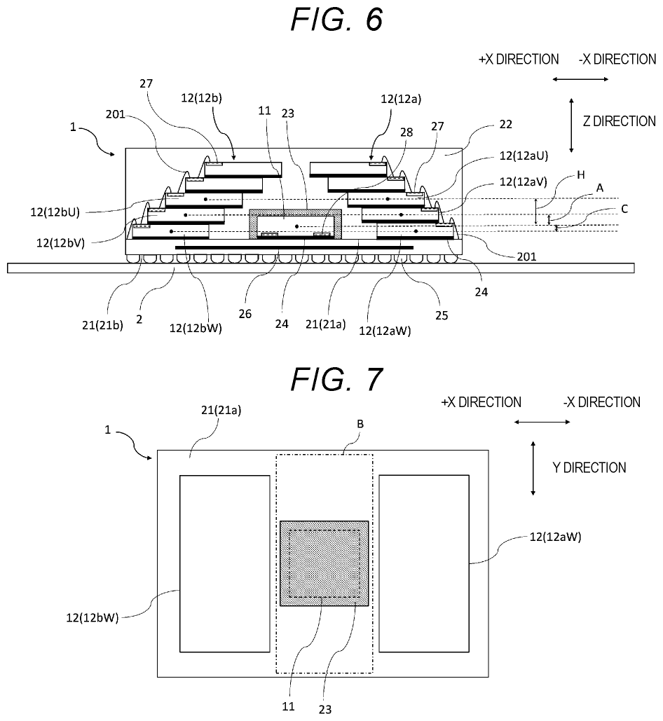

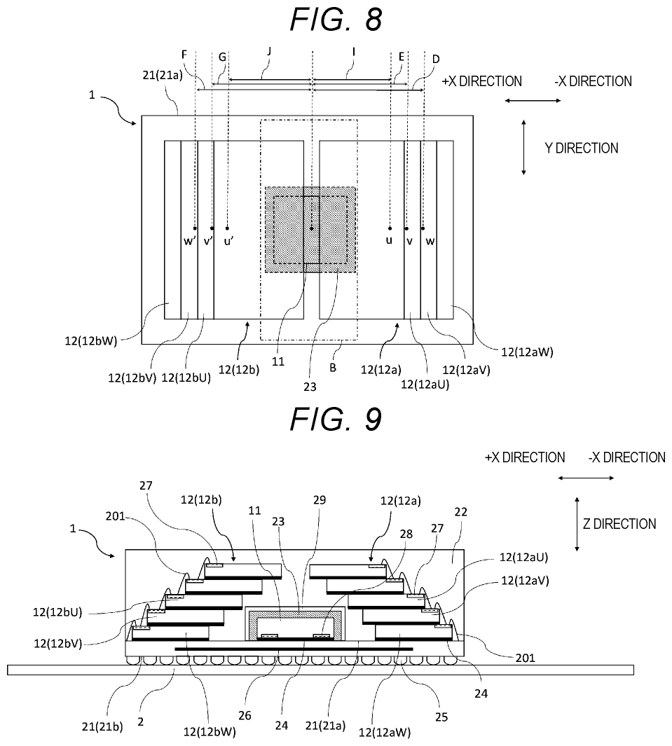

FIG. 6 shows a cross-sectional view of a semiconductor package 1 according to the second embodiment, and FIGS. 7 and 8 show top views of the semiconductor package 1 according to the second embodiment. For the sake of convenience of description, some elements such as the oscillator 14 and the EEPROM 15 provided in the semiconductor package 1 are not shown in FIGS. 6 to 8. The same elements in the semiconductor package 1 according to the second embodiment as those in the semiconductor package 1 according to the first embodiment are denoted by the same reference signs.

The semiconductor package 1 is configured with the substrate 21, the controller chip 11, a plurality of semiconductor memory chips 12, the sealing member 22, the first member 23, the mounting film 24, and the plurality of solder balls 25.

The substrate 21 is configured with the internal interconnection 26 provided inside thereof. The substrate 21 has the first surface 21a and the second surface 21b located on the opposite side to the first surface 21a.

As shown in FIGS. 6 to 8, the semiconductor memory chips 12 provided on the first surface 21a are stacked in two separate locations. The semiconductor memory chips 12 in one location will be referred to as “first memory chip group 12a” and those in the other location will be referred to as “second memory chip group 12b.” These memory chip groups are fixed onto the first surface 21a by, for example, the mounting film 24. For the sake of convenience of description, among the plurality of semiconductor memory chips 12 that configure the first memory chip group 12a, the semiconductor memory chip 12 closest to the substrate 21 in the Z direction is referred to as “memory chip 12aW” and the semiconductor memory chip 12 stacked on the memory chip 12aW is referred to as “memory chip 12aV.” Furthermore, the semiconductor memory chip 12 stacked on the memory chip 12aV is referred to as “memory chip 12aU.” Among the plurality of semiconductor memory chips 12 that configure the second memory chip group 12b, the semiconductor memory chip 12 closest to the substrate 21 in the Z direction is referred to as “memory chip 12bW” and the semiconductor memory chip 12 stacked on the memory chip 12bW is referred to as “memory chip 12bV.” Furthermore, the semiconductor memory chip 12 stacked on the memory chip 12bV is referred to as “memory chip 12bU.”

The controller chip 11 is provided on the first surface 21a, and located between the memory chips 12aW and 12bW in the X direction. The controller chip 11 is fixed onto the first surface 21a by, for example, the mounting film 24. The controller chip 11 has the electrode pads 28 and is electrically connected to the internal interconnection 26 within the substrate 21 by, for example, wire bonding or flip-chip bonding.

FIG. 7 shows only the memory chips 12aW and 12bW closest to the substrate 21 in the Z direction among the plurality of stacked semiconductor memory chips 12. In the present embodiment, the controller chip 11 is mounted in a region B between the memory chips 12aW and 12bW in the X direction. It is noted that the region B in FIG. 7 is a region surrounded by a dashed line.

Distances between the elements in the Z direction will be described with reference to FIG. 6. A distance between the elements in the Z direction means, for example, a minimum distance between center points in the Z direction of, the elements (for example, the controller chip 11 and the memory chip 12) in the semiconductor package 1. As shown in FIG. 6, in the Z direction perpendicular to the substrate 21, a distance A between the memory chip 12aV or 12bV and the controller chip 11 is greater than a distance C between the memory chip 12aW or 12bW and the controller chip 11. Furthermore, in the Z direction perpendicular to the substrate 21, a distance H between the memory chip 12aU or 12bU and the controller chip 11 is greater than the distance A between the memory chip 12aV or 12bV and the controller chip 11.

Likewise, distances between the elements in the X direction will be described with reference to FIG. 8. A distance between the elements in the X direction means, for example, a minimum distance between center points in the X direction of, the elements (for example, the controller chip 11 and the memory chip 12) in the semiconductor package 1. It is defined herein that the center point of the memory chip 12aU is u, the center point of the memory chip 12aV is v, and the center point of the memory chip 12aW is w. Likewise, it is defined herein that the center point of the memory chip 12bU is u′, the center point of the memory chip 12bV is v′, and the center point of the memory chip 12bW is w′. A distance E between the memory chip 12aV and the controller chip 11 is smaller than a distance D between the memory chip 12aW and the controller chip 11. A distance G between the memory chip 12bV and the controller chip 11 is smaller than a distance F between the memory chip 12bW and the controller chip 11. Furthermore, a distance I between the memory chip 12aU and the controller chip 11 is smaller than the distance E between the memory chip 12aV and the controller chip 11. A distance J between the memory chip 12bU and the controller chip 11 is smaller than the distance G between the memory chip 12bV and the controller chip 11.

That is, among at least n semiconductor memory chips 12 in each of the memory chip groups 12a and 12b, the (i+1)th semiconductor memory chip 12 is stacked on the i-th semiconductor memory chip 12 closer to the substrate 21. At this time, the (i+1)th semiconductor memory chip 12 is stacked in a state in which the distance of the (i+1)th semiconductor memory chip 12 from the controller chip 11 is smaller in the X direction than that of the i-th semiconductor memory chip 12 from the controller chip 11. It is noted that n mentioned herein is an integer equal to or greater than 2 and i is an integer smaller than n.

Furthermore, as shown in FIG. 8, in a plan view of the semiconductor package 1 from the Z direction, at least part of at least one semiconductor memory chip 12 that configures each of the memory chip groups 12a and 12b overlaps the region B that contains the controller chip 11 in the X and Y directions.

At least one or more semiconductor memory chips 12 that configure each of the memory chip groups 12a and 12b each have the electrode pad 27. The semiconductor memory chips 12 are electrically connected to each other by wire bonding in such a manner, for example, that the wire 201 is connected to the electrode pad 27. The at least one or more semiconductor memory chips 12 that configure each of the memory chip group 12a and 12b are electrically connected to the internal interconnection 26 within the substrate 21 via the electrode pad 27. The controller chip 11 has the electrode pads 28 and is electrically connected to the internal interconnection 26 by, for example, wire bonding or flip-chip bonding. The at least one or more semiconductor memory chips 12 that configure each of the memory chip groups 12a and 12b can be electrically connected to the controller chip 11 via the internal interconnection 26.

The sealing member 22 is a member that seals the controller chip 11 and the memory chip groups 12a and 12b on the substrate 21.

The mounting film 24 that fixes the controller chip 11 may be higher in thermal conductivity than the sealing member 22. In this case, the mounting film 24 functions to efficiently transfer the heat of the controller chip 11 to the substrate 21.

The first member 23 is provided on the first surface 21a and covers at least part of surroundings of the controller chip 11. The surroundings refer herein to the surfaces other than the surface of the controller chip 11 on which the controller chip 11 is in contact with the substrate 21. Furthermore, the first member 23 is located between the controller chip 11 and the semiconductor memory chip 12 in the X direction. The first member 23 is lower in thermal conductivity than the sealing member 22 and the heat generated by the controller chip 11 is difficult to be transferred to the semiconductor memory chip 12 by the first member 23.

The substrate 21 has the solder balls 25 provided on the second surface 21b and can be, therefore, electrically connected to the circuit board 2 of the electronic apparatus via the solder balls 25.

In the structure described above, the first member 23 makes it difficult to transfer the heat of the controller chip 11 to the sealing member 22 and also the other semiconductor chips such as the semiconductor memory chips 12. Furthermore, the heat of the controller chip 11 is dissipated in the direction of the circuit board 2 via the mounting film 24, the substrate 21, and the solder balls 25. As a result, the memory chip groups 12a and 12b, each of which is structured such that at least part of at least one semiconductor memory chip 12 is stacked to overlap the region B containing the controller chip 11 in the X and Y directions in a plan view of the semiconductor package 1 from the Z direction, are less influenced by the heat. Therefore, it is possible to reduce the influence of the thermal conduction on the other semiconductor chips such as the semiconductor memory chips 12 within the semiconductor package 1 and prevent a decline in function due to the heat.

(Modification)

As shown in FIG. 9, the semiconductor package 1 according to the present embodiment may be configured with the second member 29 provided between the first member 23 and the sealing member 22, similarly to the modification of the first embodiment.

### Third Embodiment

A structure of the semiconductor package 1 according to a third embodiment will next be described.

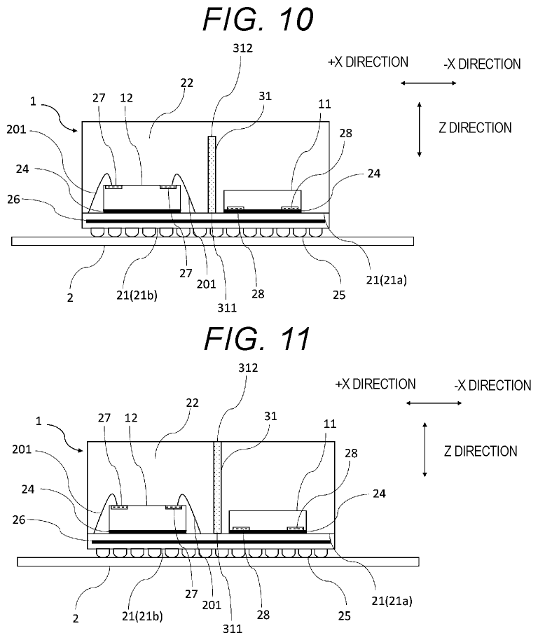

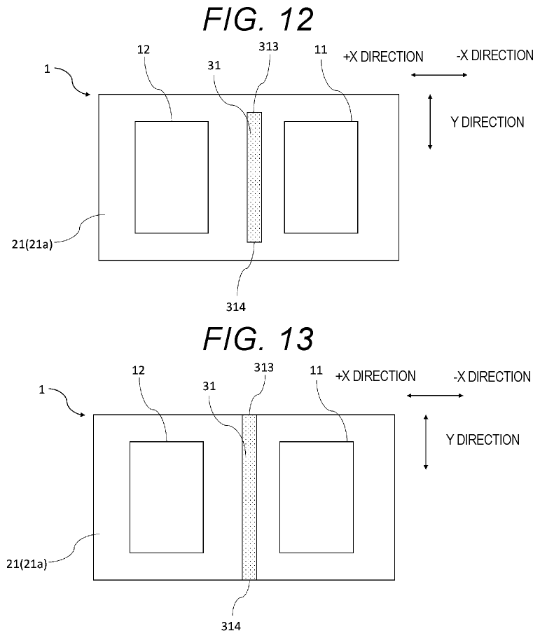

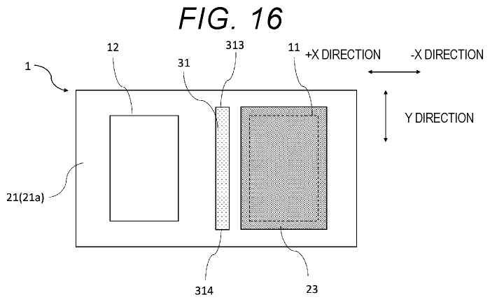

FIGS. 10, 11, 14, and 15 are cross-sectional views of the semiconductor package 1 according to the present embodiment, and FIGS. 12, 13, and 16 are top views of the semiconductor package 1 according to the present embodiment. For the sake of convenience of description, some elements, such as the oscillator 14 and the EEPROM 15, provided in the semiconductor package 1 are not shown in FIGS. 10 to 16.

The same elements in the semiconductor package 1 according to the third embodiment as those in the semiconductor package 1 according to the first embodiment are denoted by the same reference signs. As shown in FIGS. 10 to 16, the semiconductor package 1 according to the third embodiment differs from that according to the first embodiment in that a wall member 31 is disposed between the semiconductor memory chip 12 and the controller chip 11 as an alternative to the first member 23 that covers at least part of the surroundings of the controller chip 11.

The wall member 31 has a first end portion 311, a second end portion 312, a third end portion 313, and a fourth end portion 314. The end portion that is in contact with the first surface 21a of the substrate 21 is the first end portion 311, and the end portion opposite to the first end portion 311 is the second end portion 312. One of the end portions generally perpendicular to the first surface 21a is the third end portion 313, and the end portion opposite to the third end portion 313 is the fourth end portion 314. The wall member 31 is a wall-like member provided for the purpose of preventing heat generated by the controller chip 11 from being transferred to the other semiconductor chips within the semiconductor package 1 via the sealing member 22.

As shown in FIG. 10, the wall member 31 may extend in the Z direction beyond a thickness of the controller chip 11 in the Z direction. Owing to this, the second end portion 312 may be sealed by the sealing member 22 in the Z direction. Alternatively, as shown in FIG. 11, the second end portion 312 may be exposed to a surface of the sealing member 22 in the Z direction.

FIGS. 12 and 13 are plan views from the Z direction of the semiconductor package 1 according to the present embodiment, and the sealing member 22 is not shown in FIGS. 12 and 13 for the sake of convenience of description. A width of the wall member 31 along the Y direction maybe greater than a width of the controller chip 11 along the Y direction. Therefore, as shown in FIG. 12, the third end portion 313 and the fourth end portion 314 may be sealed by the sealing member 22 in the Y direction. As shown in FIG. 13, the third end portion 313 and the fourth end portion 314 may be exposed to the surface of the sealing member 22 in the Y direction. Alternatively, one of the third end portion 313 and the fourth end portion 314 may be exposed to the surface of the sealing member 22 and the other end portion may be sealed by the sealing member 22 in the Y direction.

The wall member 31 differs in thermal conductivity from the sealing member 22. The wall member 31 may be made from, for example, phenol resin, epoxy resin, polyethylene terephthalate (PET), carbon black (carbon fine particles at the diameter of approximately 3 to 500 nm), silica (silicon dioxide), or a mixture thereof. When a content ratio of the material (for example, metal such as carbon black or silica) having high thermal conductivity is low, the thermal conductivity of the wall member 31 is lower than that of the sealing member 22. By making the thermal conductivity of the wall member 31 lower than that of the sealing member 22, the heat generated from the controller chip 11 is difficult to be transferred to the other semiconductor chips such as the semiconductor memory chip 12 within the semiconductor package 1. Furthermore, the heat of the controller chip 11 is dissipated in the direction of the circuit board 2 via the mounting film 24, the substrate 21, and the solder balls 25.

Furthermore, the wall member 31 may be configured from a synthetic metal such as Al—Sic. In this case, the wall member 31 is higher in thermal conductivity than the sealing member 22. The heat generated by the controller chip 11 is transferred to the wall member 31 first, and then dissipated in a direction of the substrate 21 in a case where the end portions other than the first end portion 311 are sealed by the sealing member 22, and dissipated in the direction of the substrate 21 and outside of the semiconductor package 1 in a case where any one of the end portions other than the first end portion 311 is exposed to the surface of the sealing member 22.

As already described, whether the wall member 31 is higher or lower in thermal conductivity than the sealing member 22, it is possible to reduce the influence of the thermal conduction on the other semiconductor chips such as the semiconductor memory chip 12 within the semiconductor package 1 and prevent a decline in function due to the heat.

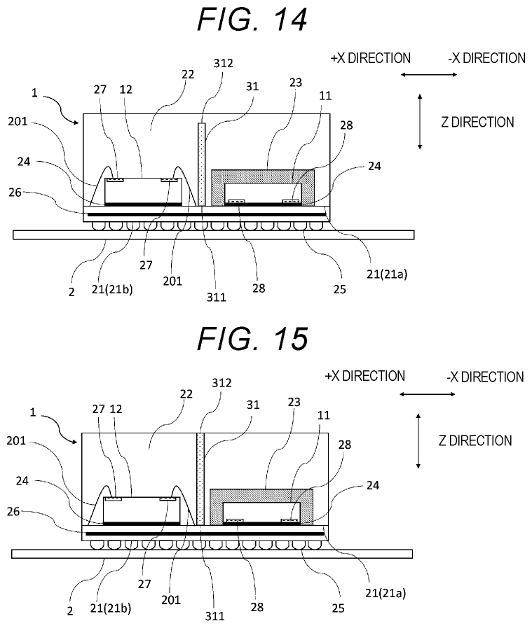

Moreover, as shown in FIGS. 14 to 16, the semiconductor package 1 according to the present embodiment may be configured with the first member 23 provided on the surroundings of the controller chip 11 similarly to the first embodiment.

Furthermore, the semiconductor package 1 according to the present embodiment may be configured with the second member 29 provided between the first member 23 and the sealing member 22 in the X direction similarly to the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor package comprising:
a substrate having a first surface;
at least one memory chip including a first memory chip provided on the first surface;
a controller chip configured to control the first memory chip, and provided on the first surface to be spaced apart from the first memory chip;
a sealing member sealing the first memory chip and the controller chip; and
a first member that covers at least part of the controller chip and has a thermal conductivity that is lower than that of the sealing member.

2. The semiconductor package according to claim 1, wherein
the first member is located between the first memory chip and the controller chip.

3. The semiconductor package according to claim 2, further comprising
a second member having a thermal conductivity lower than that of the first member and disposed between the first member and the sealing member.

4. The semiconductor package according to claim 1, wherein
the substrate further comprises a mounting film that fixes the first memory chip and the controller chip onto the first surface, and has a higher thermal conductivity than that of the sealing member.

5. The semiconductor package according to claim 4, wherein
the first memory chip and the controller chip are in contact with the substrate.

6. The semiconductor package according to claim 5, wherein
the substrate has an internal wiring layer and a solder ball on a second surface opposite to the first surface, and the controller chip has an electrode pad, and
the controller chip is electrically connected to the internal wiring layer via the electrode pad, and the internal wiring layer is configured to be electrically connected to an external circuit board via the solder ball.

7. The semiconductor package according to claim 1, wherein
the at least one memory chip includes
a first memory chip group that includes a plurality of the memory chips stacked on the first surface; and
a second memory chip group that includes a plurality of the memory chips stacked on the first surface, and
the controller chip is located between the first memory chip group and the second memory chip group.

8. The semiconductor package according to claim 7, wherein
the first memory chip group includes the first memory chip and a third memory chip,
a distance in a first direction perpendicular to the substrate between the third memory chip and the controller chip is greater than a distance in the first direction between the first memory chip and the controller chip, and
a distance in a second direction parallel to the substrate and crossing the first direction, between the third memory chip and the controller chip is smaller than the distance between the first memory chip and the controller chip; and
the second memory chip group includes a second memory chip and a fourth memory chip,
a distance in the first direction between the fourth memory chip and the controller chip is greater than a distance in the first direction between the second memory chip and the controller chip, and
the distance in the second direction between the fourth memory chip and the controller chip is smaller than the distance in the second direction between the second memory chip and the controller chip.

9. The semiconductor package according to claim 8, wherein
the first memory chip group further includes a fifth memory chip,
a distance in the first direction between the fifth memory chip and the controller chip is greater than the distance in the first direction between the third memory chip and the controller chip, and
the distance in the second direction between the fifth memory chip and the controller chip is smaller than the distance in the second direction between the third memory chip and the controller chip; and
the second memory chip group further includes a sixth memory chip,
a distance in the first direction between the sixth memory chip and the controller chip is greater than the distance in the first direction between the fourth memory chip and the controller chip, and
the distance in the second direction between the sixth memory chip and the controller chip is smaller than the distance in the second direction between the fourth memory chip and the controller chip.

10. The semiconductor package according to claim 8, wherein
when viewed along the first direction, the controller chip overlaps at least part of at least one memory chip in the first memory chip group and at least one memory chip in the second memory chip group.

11. A semiconductor package comprising:
a substrate having a first surface;
a memory chip in contact with the first surface;
a controller chip configured to control the memory chip and in contact with the first surface;
a sealing member sealing the memory chip and the controller chip; and
a wall member provided on the first surface, disposed between the memory chip and the controller chip, having one end in contact with the first surface, and having a thermal conductivity that is different from that of the sealing member.

12. The semiconductor package according to claim 11, wherein
a length of the wall member in a first direction perpendicular to the substrate is greater than a length of the controller chip in the first direction, and a length of the wall member in a second direction parallel to the substrate and crossing the first direction, is greater than a length of the controller chip in the second direction.

13. The semiconductor package according to claim 12, wherein
an end portion of the wall member is exposed to a surface of the sealing member.

14. The semiconductor package according to claim 12, wherein
the sealing member seals the wall member.

15. The semiconductor package according to claim 11, wherein
the wall member has a lower thermal conductivity than that of the sealing member.

16. The semiconductor package according to claim 11, wherein
the wall member has a higher thermal conductivity than that of the sealing member.

17. The semiconductor package according to claim 11, further comprising
a first member that covers at least part of the controller chip and has a lower thermal conductivity than that of the sealing member.

18. The semiconductor package according to claim 11, wherein
the substrate further comprises a mounting film that fixes the first memory chip or the controller chip onto the first surface, and has a higher thermal conductivity than that of the sealing member.

19. The semiconductor package according to claim 11, wherein
the substrate has an internal wiring layer and a solder ball on a second surface opposite to the first surface,
the controller chip has an electrode pad, and
the controller chip is electrically connected to the internal wiring layer via the electrode pad, and the internal wiring layer is configured to be electrically connected to an external circuit board via the solder ball.

20. The semiconductor package according to claim 11, further comprising:
a first member that covers the controller chip and has a lower thermal conductivity than that of the sealing member; and
a second member that covers the first member and has a lower thermal conductivity than that of the first member.
